(19) United States
(12) Patent Application Publication
(10) Pub. No.: US 2008/0286916 A1
(43) Pub. Date: Nov. 20, 2008

(54) METHODS OF STRESSING TRANSISTOR CHANNEL WITH REPLACED GATE

(76) Inventors: Zhijiong Luo, Carmel, NY (US); Huilong Zhu, Poughkeepsie, NY (US); Yung Fu Chong, Singapore (SG); Brian L. Tessier, Poughkeepsie, NY (US)

Correspondence Address: HOFFMAN WARNICK LLC, 75 STATE ST, 14TH FL, ALBANY, NY, 12207, US

(21) Appl. No.: 12/179,042

(22) Filed: Jul. 24, 2008

Related U.S. Application Data
(62) Division of application No. 11/421,910, filed on Jun. 2, 2006.

(51) Int. Cl. H01L 21/336

(52) U.S. Cl. 438/197; 257/E21.409

(57) ABSTRACT

Methods of stressing a channel of a transistor with a replaced gate and related structures are disclosed. A method may include providing an intrinsically stressed material over the transistor including a gate thereof; removing a portion of the intrinsically stressed material over the gate; removing at least a portion of the gate, allowing stress retained by the gate to be transferred to the channel; replacing (or refilling) the gate with a replacement gate; and removing the intrinsically stressed material. Removing and replacing the gate allows stress retained by the original gate to be transferred to the channel, with the replacement gate maintaining (memorizing) that situation. The methods do not damage the gate dielectric.

This paper is being filed in a divisional patent application of U.S. patent application Ser. No. 11/421,910, filed on Jun. 2, 2006, currently pending.

### BACKGROUND OF THE INVENTION

1. Technical Field

The invention relates generally to semiconductor device fabrication, and more particularly, to methods of stressing a channel of a transistor with a replaced gate, and related structures.

2. Background Art

The application of stresses to channels of field effect transistors (FETs) is known to improve their performance. When applied in a longitudinal direction (i.e., in the direction of current flow), tensile stress is known to enhance electron mobility (or n-channel FET (nFET) drive currents) while compressive stress is known to enhance hole mobility (or p-channel FET (pFET) drive currents).

One manner of providing this stress is referred to as stress memorization technique (SMT), which includes applying an intrinsically stressed material (e.g., silicon nitride) over a channel region and annealing to have the stress memorized in, for example, the gate polysilicon or the diffusion regions. The stressed material is then removed. The stress, however, remains and improves electron or hole mobility, which improves overall device performance. The anneal step may be provided as part of a dopant activation anneal. One problem with conventional SMT is that only the performance of the nFET is enhanced, while the performance of the pFET is degraded. Accordingly, it is difficult to use SMT to enhance both nFET and pFET performance.

Another challenge is applying a strong stress in the channel. More specifically, the stronger the stress provided in the channel, typically the better the performance. Unfortunately, the induced stress in the channel is only a fraction of that provided by the intrinsically stressed material.

In view of the foregoing, there is a need in the art for a solution to the problems of the related art.

### SUMMARY OF THE INVENTION

Methods of stressing a channel of a transistor with a replaced gate and related structures are disclosed. A method may include providing an intrinsically stressed material over the transistor including a gate thereof; removing a portion of the intrinsically stressed material over the gate; removing at least a portion of the gate, allowing stress retained by the gate to be transferred to the channel; replacing (or refilling) the gate with a replacement gate; and removing the intrinsically stressed material. Removing and replacing the gate allows stress retained by the original gate to be transferred to the channel, with the replacement gate maintaining (memorizing) that situation. The methods do not damage the gate dielectric. A structure may include a transistor having a channel including a first stress that is one of a compressive and tensile and a gate including a second stress that is the other of compressive and tensile.

A first aspect of the invention provides a method of stressing a channel of a transistor, the method comprising the steps of: providing an intrinsically stressed material over the transistor including a gate thereof, removing a portion of the intrinsically stressed material over the gate; removing at least a portion of the gate, allowing stress retained by the gate to be transferred to the channel; replacing the gate with a replacement gate; and removing the intrinsically stressed material.

A second aspect of the invention provides a method of stressing a channel of a transistor, the method comprising: first providing a metal layer over the transistor including a gate and a source/drain region thereof; second providing an intrinsically stressed material over the transistor including the gate and the source/drain region thereof; removing a portion of the intrinsically stressed material over each gate; removing a portion of the metal layer over the gate; removing at least a portion of the gate; replacing the gate with a metal; annealing to form a stressed silicide gate and stressed silicide portions in the source/drain region; and removing the intrinsically stressed material and the metal layer.

A third aspect of the invention provides a structure comprising: a transistor having a channel including a first stress that is one of compressive and tensile and a gate including a second stress that is the other of compressive and tensile.

A fourth aspect of the invention is directed to a structure comprising: a transistor having a gate including a stressed silicide for memorizing a stress therein; and a source region and a drain region each including a stress silicide portion for memorizing the stress.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows an initial structure according to one embodiment of the invention.

FIGS. 2-8 show one embodiment of a method according to the invention.

FIG. 9 shows one embodiment of a structure according to the invention.

FIGS. 10-19 show a second embodiment of a method according to the invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

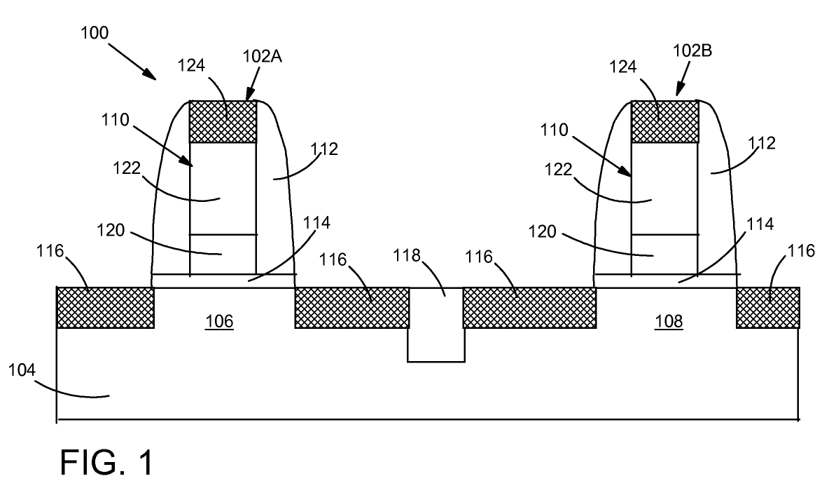

Referring to the drawings, FIG. 1 shows an initial structure 100 for methods according to various embodiments of the invention. Initial structure 100 may include one or more transistors 102A, 102B, i.e., field effect transistors (FETs), on a substrate 104. Transistor 102A includes an n-type-channel 106 and transistor 102B includes a p-type-channel 108, resulting in an nFET 102A and pFET 102B. Each transistor 102A, 102B may further include a gate 110, a spacer 112 about gate 110, a gate dielectric 114 and source/drain regions 116. Each part may include any now known or later developed material appropriate for its function. For example, substrate 104 may include silicon, spacer 112 may include silicon nitride (Si₃N₄), gate dielectric 114 may include silicon dioxide (SiO₂), and source/drain regions 116 may include doped silicon and a silicide such as nickel silicide. In addition, initial structure 100 may include a shallow trench isolation (STI) region 118, e.g., of silicon dioxide (SiO₂), separating transistors 102A, 102B. In one embodiment, each gate 110 may include a silicide portion 124, e.g., nickel silicide, over a polysilicon germanium portion 122 over a polysilicon portion 120. However, these portions are not essential to the invention. It is understood that the above-described initial structure 100 is meant to be illustrative only and that the teachings of the invention may be applied to other structures. At this stage, all high temperature anneals have preferably been completed, including a dopant activation anneal. For example, all dopants in FIG. 1 may be already in place and electrically active.

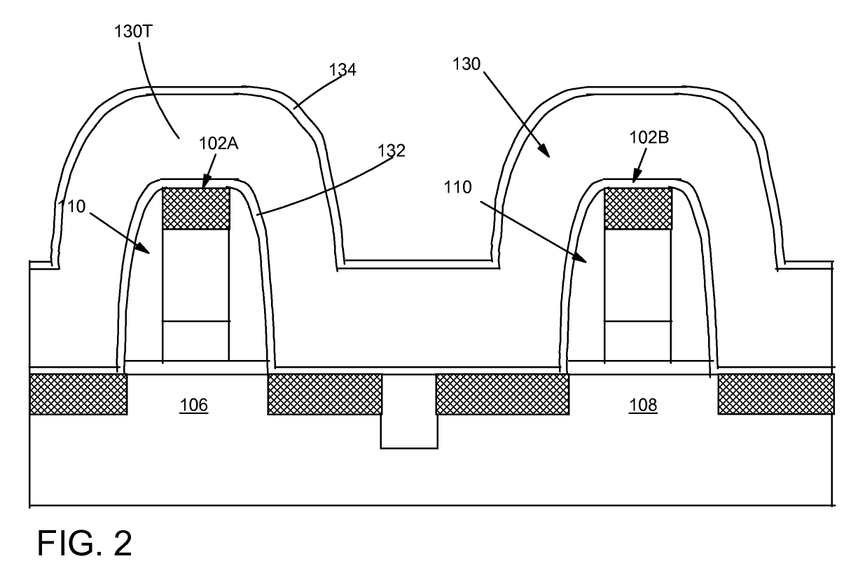

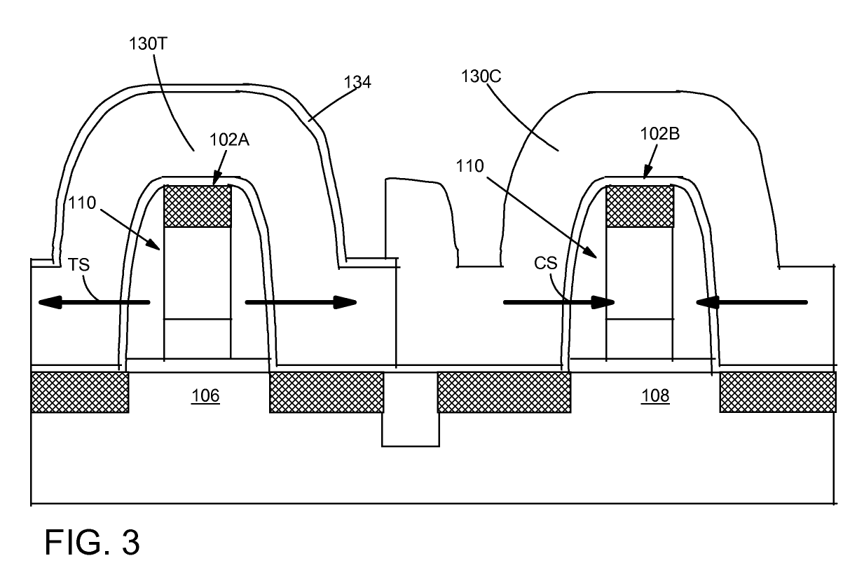

Turning to FIGS. 2-3, a first step of the method includes providing an intrinsically stressed material 130 over a transistor(s) 102A, 102B including gate 110 thereof. Intrinsically stressed material 130 may include any now known or later developed material for imparting an appropriate stress to channels 106, 108 such as intrinsically stressed silicon nitride (Si₃N₄). In particular, as shown in FIG. 3, this step may include providing an intrinsically tensilely stressed material 130T over n-channel 106 transistor 102A and an intrinsically compressively stressed material 130C (FIG. 3) over a p-channel 108 transistor 102B. Where both tensile and compressive stress materials are used, it is referred to in the art as a dual stress liner. Although the method will be described with both transistors 102A, 102B involved in the processing, it is understood that the teachings may be applied to a single transistor, if desired. This step may include any now known or later developed steps for providing intrinsically stressed material 130, as a single layer or as a dual stress liner. For example, as shown in FIG. 2, in one embodiment, a protective layer 132 of, for example, silicon dioxide (SiO₂), may be provided over transistors 102A, 102B to protect them. Next, a tensilely intrinsically stressed material 130T may be deposited over transistors 102A, 102B. Optionally, a protective layer 134 (e.g., silicon dioxide (SiO₂)) may be deposited over tensilely intrinsically stressed material 130T (only shown in FIGS. 2-3).

Next, as shown in FIG. 3, in order to form a dual stress liner, tensilely intrinsically stressed material 130T is removed over transistor 102B, which includes p-type channel 108, and compressively intrinsically stressed material 130C is formed. This step may include patterning a photoresist (not shown) over transistor 102A, performing an etch, e.g., a reactive ion etch (RIE), to remove tensilely intrinsically stressed material 130T over transistor 102B, depositing compressively intrinsically stressed material 130C, patterning a photoresist (not shown) over transistor 102B, and performing an etch, e.g., RIE, to remove compressively intrinsically stressed material 130C over transistor 102A. As a result of the above step, protective layer 134 (FIGS. 2-3 only) ends up being provided over intrinsically tensilely stressed material 130T only. In addition, a tensile stress TS is applied to transistor 102A and a compressive stress CS is applied to transistor 102B.

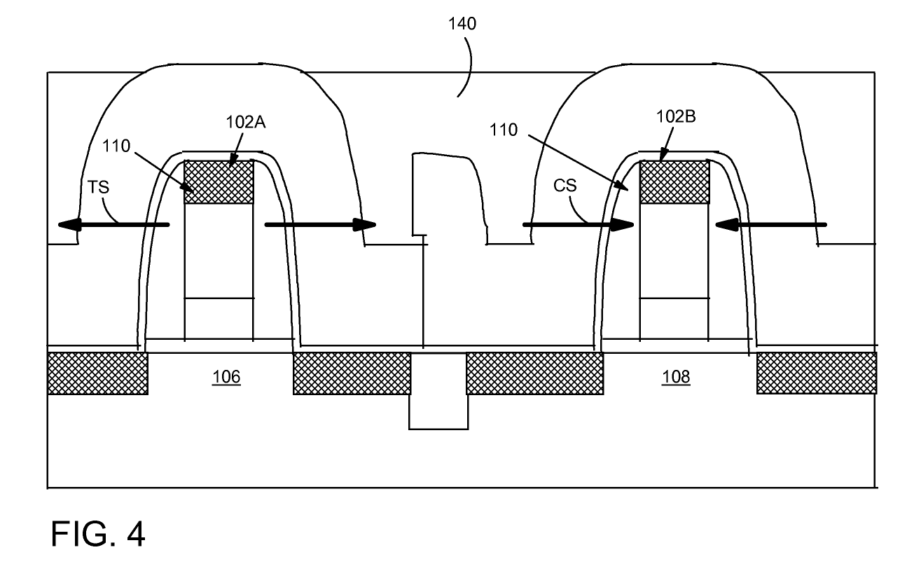

As shown in FIG. 4, a next step may include providing a planarizing layer 140 of, for example, silicon dioxide (SiO₂) about each gate 110, which acts to stabilize and fill, inter alia, an area between transistors 102A, 102B for subsequent processing.

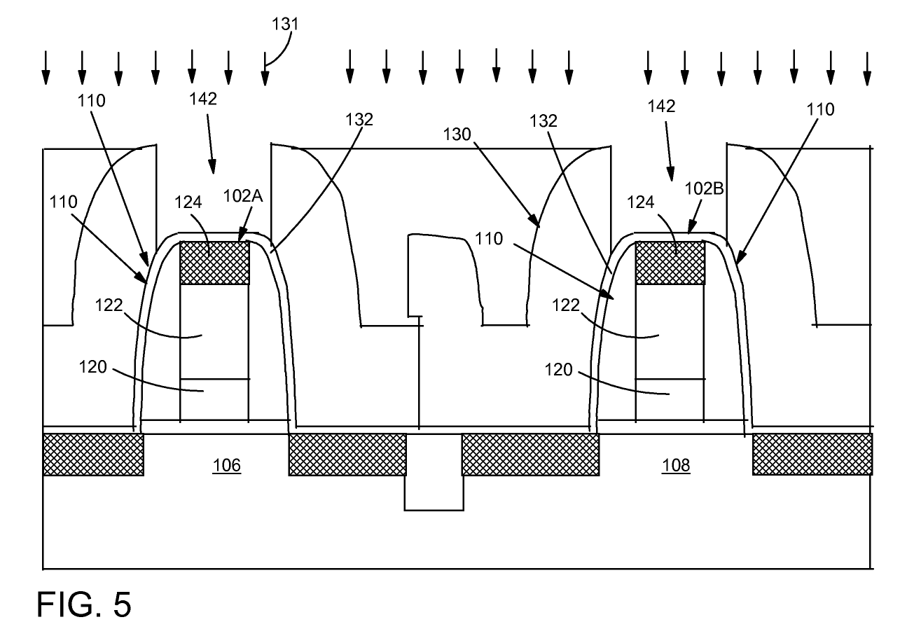

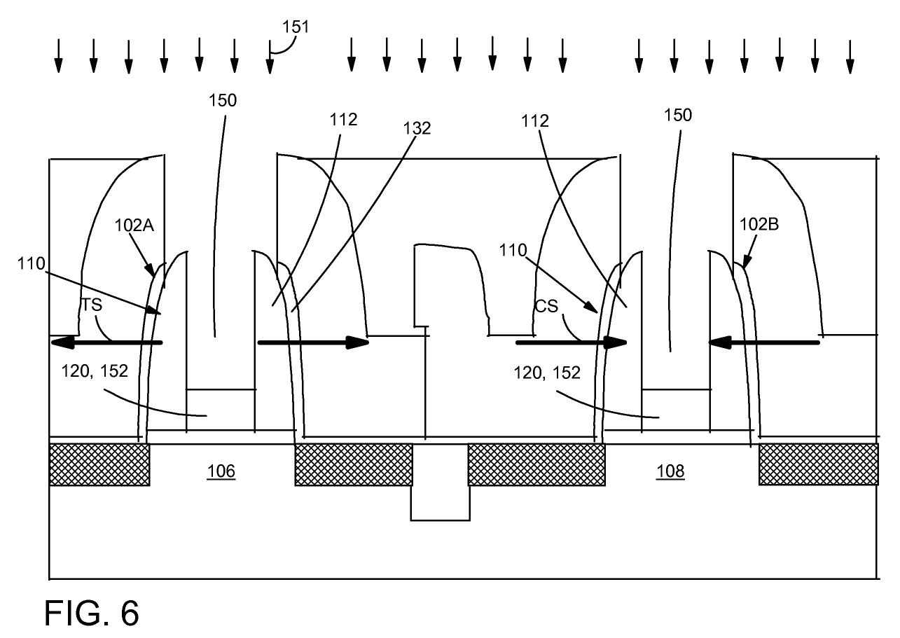

Next, as shown in FIG. 5, a portion 142 of intrinsically stressed material 130 is removed over gate(s) 110. This step may include patterning a photoresist and performing a RIE 131 to protective layer 132. As a result of this step, gate(s) 110 is exposed. Next, as shown in FIG. 6, at least a portion 150 of gate(s) 110 is removed. In one embodiment, gate(s) 110 is removed to polysilicon portion 120, where different portions are provided. The particular etching processes used may be particular to the material to be removed. In one embodiment, a RIE 151 selective to polysilicon portion 120 may be used for each material of gate(s) 110, e.g., as shown in FIG. 5, protective layer 132 (SiO₂), silicide portion 124 (FIG. 5), and polysilicon germanium portion 122 (FIG. 5). In any event, at least a portion 152 of gate(s) 110 (including at least a part of polysilicon portion 120) is retained to maintain spacer(s) 112 in position. When portion(s) 150 is removed, it allows stress CS and/or TS retained by gate(s) 110 to be transferred to a respective channel 106, 108. That is, tensile stress TS retained by gate 110 of transistor 102A is transferred to n-type channel 106, and compressive stress CS retained by gate 110 of transistor 102B is transferred to p-type channel 108, which further improves performance of the resulting devices.

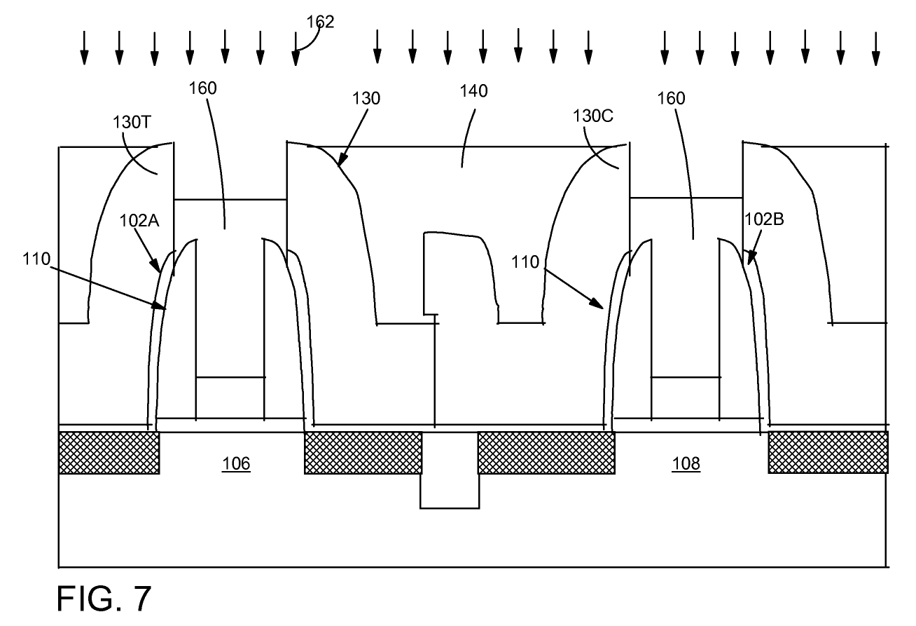

FIG. 7 shows a next step in which portion(s) 150 (FIG. 6) of gate(s) 110 are replaced, i.e., refilled, with a replacement gate(s) 160. An appropriate liner (not shown) for replacement gate(s) 160 of, for example, titanium nitride (TiN) may be formed as needed. Replacement gate(s) 160 may include any now known or later developed gate material. In one embodiment, replacement gate(s) 160 may include tungsten (W). As also shown in FIG. 7, this step may include an etch back 162 of replacement gate(s) 160 so it is below a surface of planarizing layer 140.

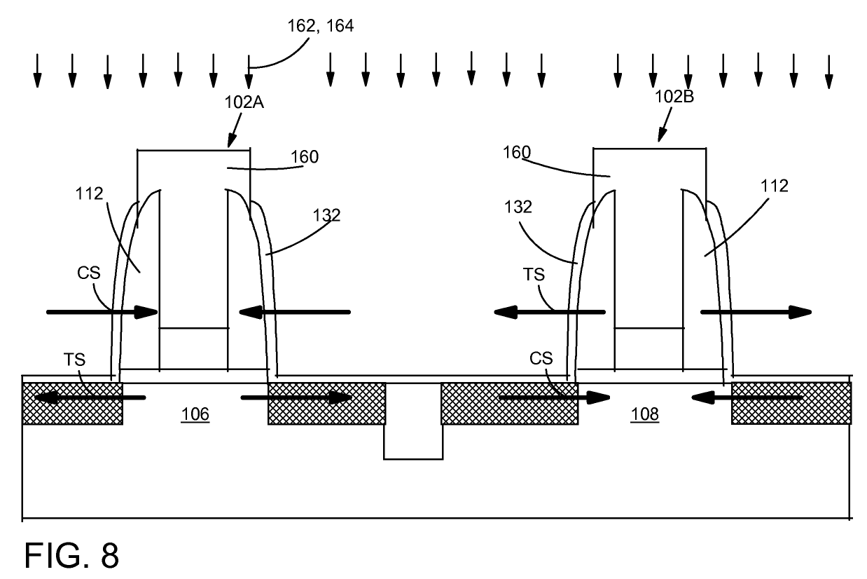

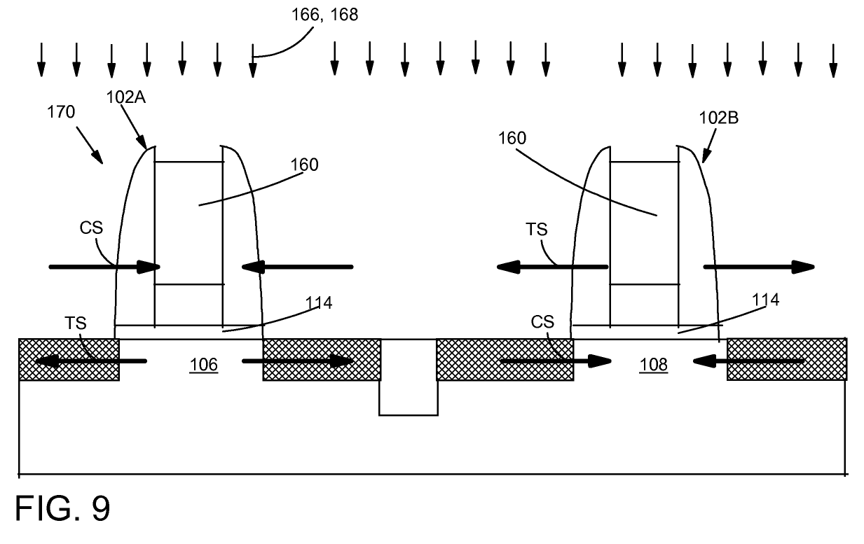

FIG. 8 shows the next step of removing intrinsically stressed material 130 (FIG. 7), e.g., by RIE 162 of planarizing layer 140 (FIG. 7) and wet etching 164 intrinsically stressed material 130 (FIG. 7) selective to protective layer 132. As a result of this step, replacement gate(s) 160 maintains (memorizes) the stresses transferred to channels 106, 108. In addition, each replacement gate 160 includes a stress that is opposite of that of a respective channel 106, 108. For example, when stress liner 130T (FIG. 7) is removed, the tensile stress applied to spacer 112 is released, thus causing it to compress replacement gate 160. Similarly, when stress liner 130C (FIG. 7) is removed, the compressive stress applied to spacer 112 is removed, thus causing it to tensilely pull on replacement gate 160. As a result, replacement gate 160 of transistor 102A includes a compressive stress CS, while its respective channel 106 includes a tensile stress TS. Similarly, replacement gate 160 of transistor 102B includes a tensile stress TS, while its respective channel 108 includes a compressive stress CS. Subsequent processing may include, as shown in FIG. 9, etching back replacement gate(s) 160 using, for example, a wet etch 166 of replacement gate(s) 160 and a RIE 168 of protective layer 132 (FIG. 8). The result is a normally shaped transistor(s) 102A, 102B.

The above-described methods temporarily remove at least a portion 150 (FIG. 6) of original gate(s) 110 to allow stress TS, CS retained by gate(s) 110 to be transferred to channel(s) 106, 108 and replacement gate(s) 160 to maintain the transferred stress. In this fashion, a maximum portion of the stress of an original gate 110 is used for stress memory without damaging gate dielectric 114. The above-described methods may be used for nFETS 102A and pFETS 102B. Since the methods may be employed using low temperature, they reduce the likelihood of defect generation. In addition, there is no need to re-center the device. If desired, the process may be repeated to further enhance the stress in channel 106, 108. As shown in FIG. 9, a resulting structure 170 includes a transistor 102A or 102B having a channel 106 or 108 including a first stress that is either compressive or tensile and a (replacement) gate 160 including a second stress that is the other of compressive and tensile. For example, transistor 102A has an n-type channel 106 including a tensile stress TS and a (replacement) gate 160 having a compressive stress CS. Similarly, transistor 102B has a p-type channel 108 including a compressive stress CS and a replacement gate 160 having a tensile stress TS.

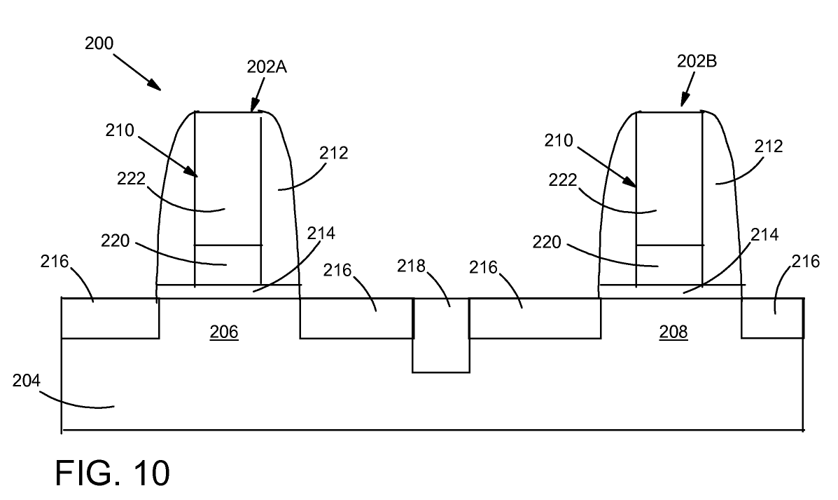

Turning to FIGS. 10-19, a second embodiment of a method is described. This embodiment begins with an initial structure 200 illustrated in FIG. 10. Initial structure 200 is substantially similar to initial structure 100 (FIG. 1), except that a source/drain region 216 does not include silicide, and silicide portion 124 (FIG. 1) is not present. Initial structure 200 may include one or more transistors 202A, 202B, i.e., field effect transistors (FETs), on a substrate 204. Transistor 202A includes an n-type-channel 206 and transistor 202B includes a p-type-channel 208, resulting in an nFET 202A and pFET 202B. Each transistor 202A, 202B may further include a gate 210, a spacer 212 about gate 210, a gate dielectric 214 and source/drain regions 216. Each part may include any now known or later developed material appropriate for its function, as describe relative to the earlier embodiments. In this embodiment, however, each gate 210 may include a polysilicon germanium portion 222 over a polysilicon portion 220. However, these portions are not essential to the invention. It is understood that the above-described initial structure 200 is meant to be illustrative only and that the teachings of the invention may be applied to other structures. At this stage, not all of the high temperature anneals have been completed.

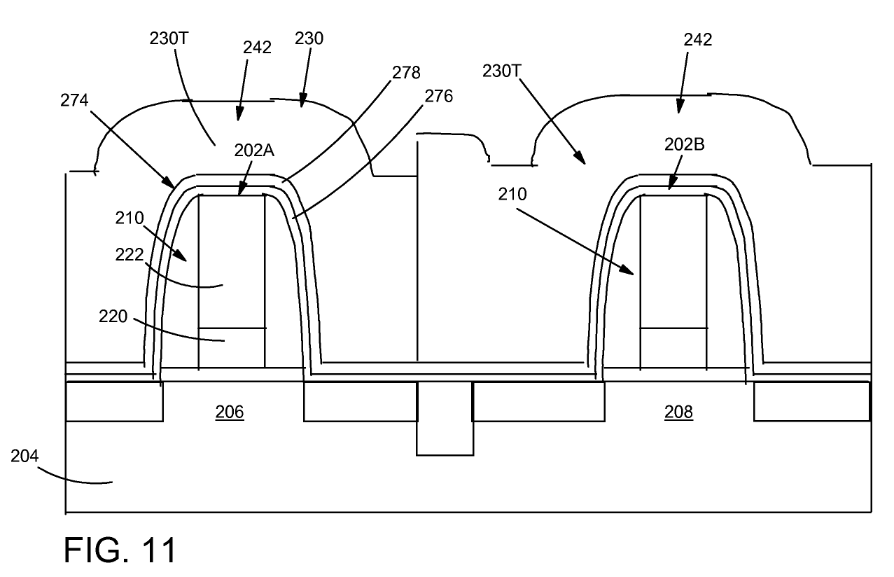

Turning to FIG. 11, a first step of the method includes providing a metal layer 274 over transistor(s) 202A, 202B including gate 210 thereof and source/drain region 216 prior to providing intrinsically stressed material 230 thereover. In one embodiment, metal layer 274 may include a nickel (Ni) layer 276 (e.g., approximately 5-15 nm) and a titanium nitride (TiN) layer 278 (e.g., approximately 5-10 nm), the purposes of which will be described below. Metals other than nickel (Ni) may also be employed such as cobalt (Co), titanium (Ti) and osmium (Os). If a metal other than nickel is used, the silicide includes that metal. As described above, intrinsically stressed material 230 may include any now known or later developed material for imparting an appropriate stress to channels 206, 208 such as intrinsically stressed silicon nitride (Si₃N₄). In particular, as shown in FIG. 11, this step may include providing an intrinsically tensilely stressed material 230T over n-channel 206 transistor 202A and an intrinsically compressively stressed material 230C over a p-channel 208 transistor 202B, which is processed similar to FIGS. 2 and 3 described above. Although the method will be described with both transistors 202A, 202B involved in the processing, it is understood that the teachings may be applied to a single transistor, if desired. This step may include any now known or later developed steps for providing metal layer 274, and providing intrinsically stressed material 230, as a single layer or as a dual stress liner, e.g., chemical vapor deposition (CVD), patterning and etching to remove appropriate material, etc.

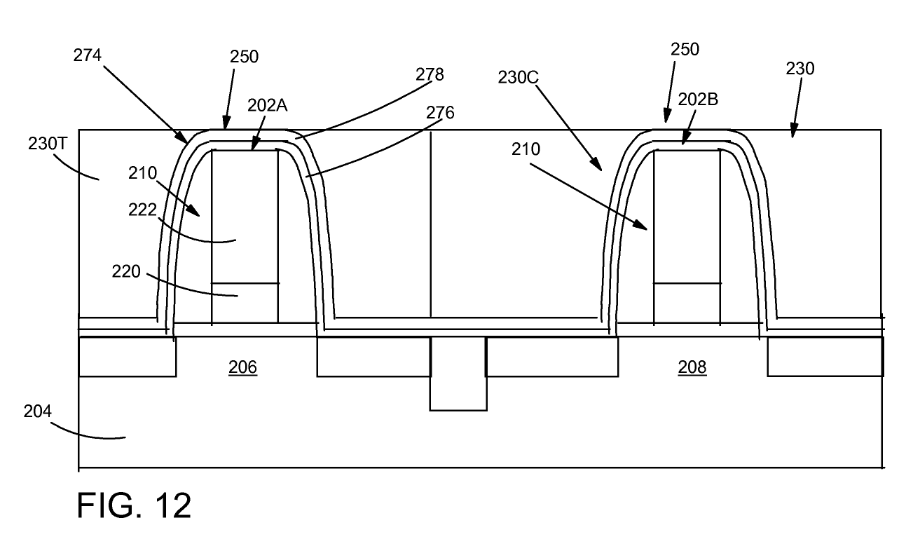

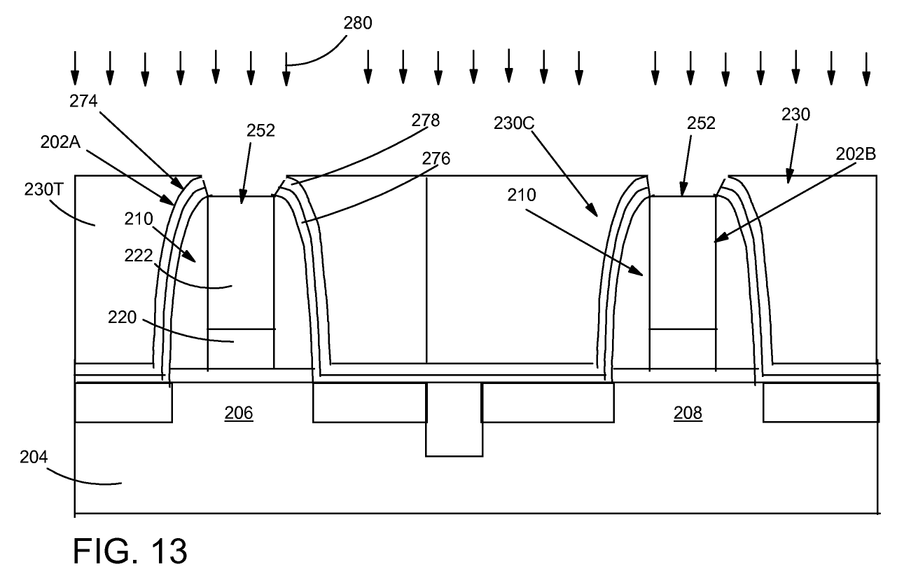

Next, as shown in FIG. 12, a portion 242 (FIG. 11) of intrinsically stressed material 230 is removed over gate(s) 210. This step may include chemical mechanical polishing (CMP). Next, as shown in FIG. 13, a portion 250 (FIG. 12) of metal layer 274 over gate(s) 210 is removed, e.g., by patterning a photoresist (not shown) and performing a wet etch 280. In the embodiment shown, nickel layer 276 and titanium nitride layer 278 are removed over gate(s) 210.

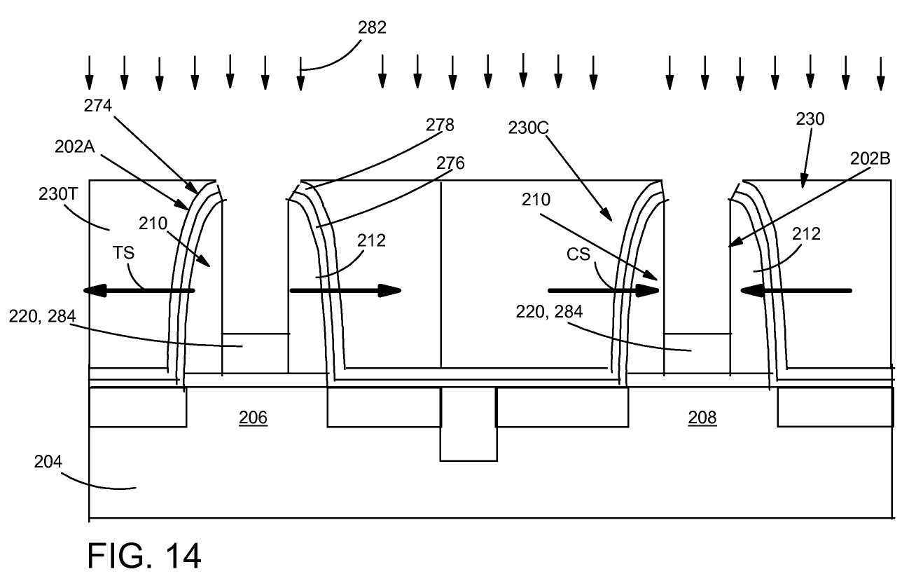

Next, as shown in FIG. 14, a portion 252 (FIG. 13) of gate(s) 210 is removed. In one embodiment, gate(s) 210 is removed to polysilicon portion 220. The etching processes used may be particular to the material to be removed. In one embodiment, a RIE 282 selective to polysilicon portion 220 may be used for each material of gate(s) 210, e.g., polysilicon germanium portion 222 (FIG. 13). In any event, at least a portion 284 of gate(s) 210 (including at least a part of polysilicon portion 220) is retained to maintain spacer(s) 212 in position. As described above, when portion(s) 252 (FIG. 13) is removed, it allows stress CS and/or TS retained by gate(s) 210 to be transferred to a respective channel 206, 208. That is, tensile stress TS retained by gate 210 of transistor 202A is transferred to n-type channel 206, and compressive stress CS retained by gate 210 of transistor 202B is transferred to p-type channel 208, which further improves performance of the resulting devices.

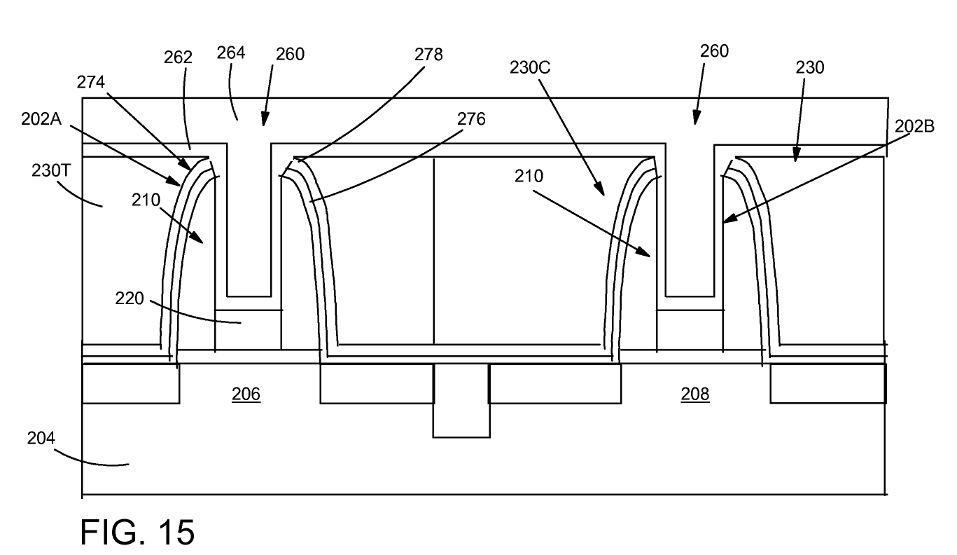

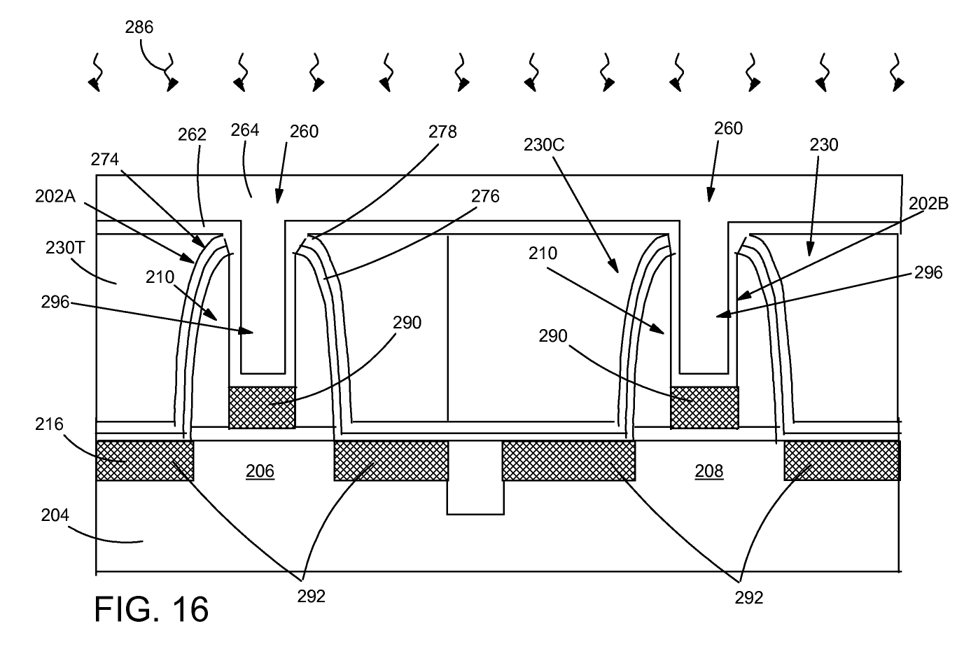

FIG. 15 shows a next step in which portion(s) 252 (FIG. 13) of gate(s) 210 are replaced, i.e., refilled, with a replacement gate(s) 260. In this embodiment, replacement gate 260 may include a nickel (Ni) layer 262 and a titanium nitride (TiN) layer 264. That is, replacement gate 260 includes a metal. A metal other than nickel (Ni) may be used such as cobalt (Co), titanium (Ti) and osmium (Os). The silicide formed includes whatever metal is used. FIG. 16 shows annealing 286 to form gate including a stressed silicide 290 and stressed silicide portions 292 in source/drain region 216. Since this step occurs prior to removal of intrinsically stressed material 230, a silicide, i.e., nickel silicide (NiSi), is formed that memorizes the stress generated by intrinsically stressed material 230 in stressed silicide 290 of replacement gate 260 and stressed silicide portions 292 of source/drain region 216. This structure allows for more stress retention in transistors 202A, 202B, and improved performance of transistors 202A, 202B.

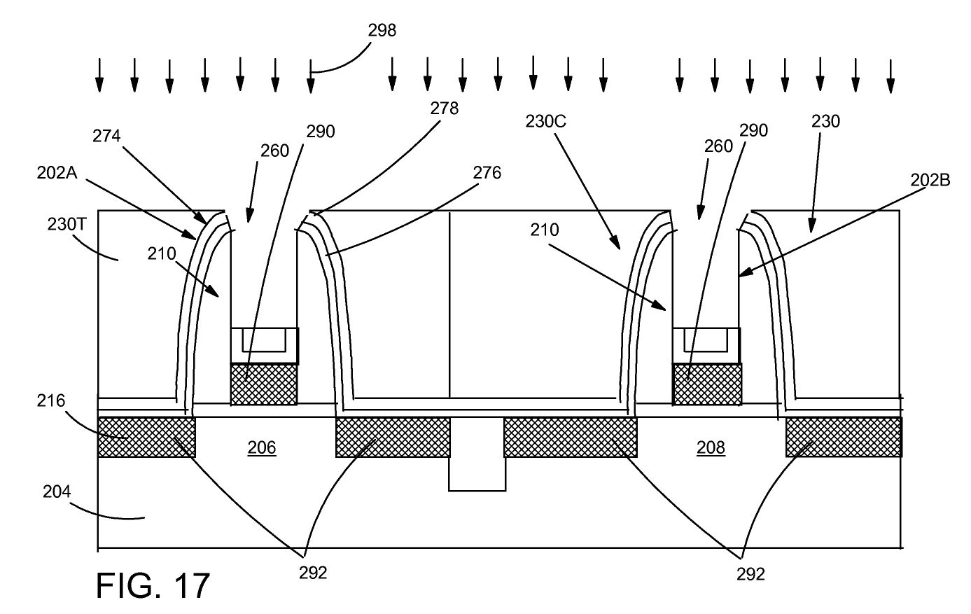

FIG. 17 shows removing at least a portion 296 (FIG. 16) of replacement gate 260 prior to removing intrinsically stressed material 230. This step may include, for example, a wet etch 298.

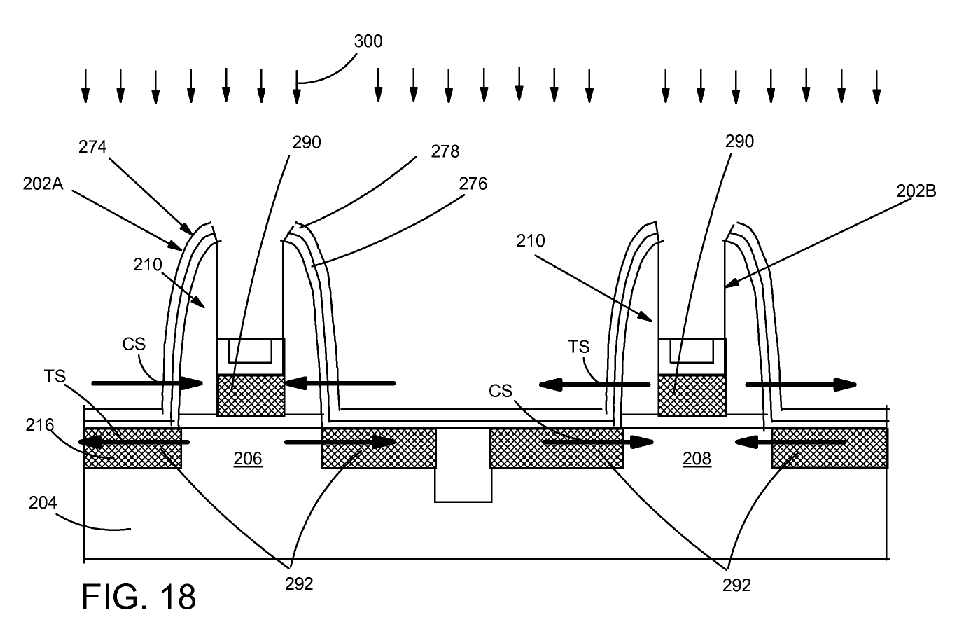

FIG. 18 shows the next step of removing intrinsically stressed material 230 (FIG. 17), e.g., by RIE 300 of intrinsically stressed material 230 (FIG. 7) selective to metal layer 274. As a result of this step, replacement gate(s) 260, i.e., stressed silicide portion(s) 290, maintains (memorizes) the stresses transferred to channels 206, 208. In addition, as described above, each replacement gate 260 includes a stress that is opposite of that of a respective channel 206, 208. For example, when stress liner 230T (FIG. 17) is removed, the tensile stress applied to spacer 212 is released, thus causing it to compress replacement gate 260. Similarly, when stress liner 230C (FIG. 17) is removed, the compressive stress applied to spacer 212 is removed, thus causing it to tensilely pull on replacement gate 260. As a result, replacement gate 260 of transistor 202A includes a compressive stress CS, while its respective channel 206 includes a tensile stress TS. Similarly, replacement gate 260 of transistor 202B includes a tensile stress TS, while its respective channel 208 includes a compressive stress CS. Furthermore, in this embodiment, transistor 202A, 202B each have gate 210 including a stressed silicide 290 for memorizing a stress therein, and source/drain region 216 each including a stress silicide portion 292 for memorizing the stress.

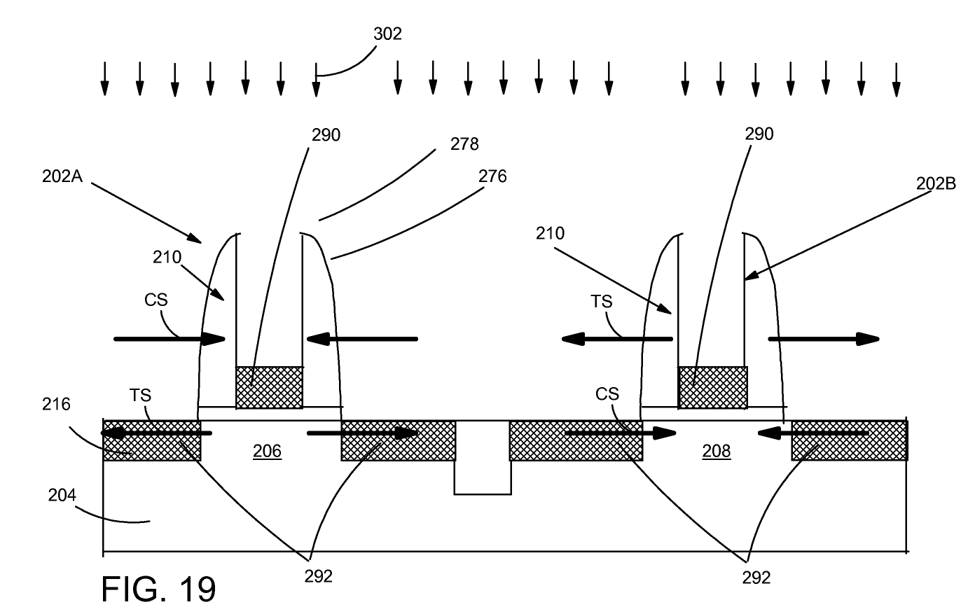

FIG. 19 shows another step of removing metal layer 274 (FIG. 17), e.g., by a wet etch 302 of titanium nitride layer 278 (FIG. 18) and nickel layer 276 (FIG. 18) selective to stressed silicide portions 292 and stressed silicide 290. Subsequent processing may include finalizing transistors 202A, 202B in any now known or later developed fashion.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method of stressing a channel of a transistor, the method comprising:
providing an intrinsically stressed material over the transistor including a gate thereof;
removing a portion of the intrinsically stressed material over the gate;
removing at least a portion of the gate, allowing stress retained by the gate to be transferred to the channel;
replacing the gate with a replacement gate; and
removing the intrinsically stressed material.

2. The method of claim 1, wherein the providing includes providing an intrinsically tensilely stressed material over an n-channel transistor and an intrinsically compressively stressed material over a p-channel transistor.

3. The method of claim 2, wherein the providing further includes providing a protective layer over the intrinsically tensilely stressed material.

4. The method of claim 1, further comprising providing a protective layer over the transistor prior to providing the intrinsically stressed material.

5. The method of claim 4, wherein the intrinsically stressed material removing includes performing a reactive ion etch (RIE) to the protective layer.

6. The method of claim 1, wherein the gate includes a silicide portion over a polysilicon germanium portion over a polysilicon portion.

7. The method of claim 6, wherein the gate removing includes performing a reactive ion etch (RIE) selective to the polysilicon portion.

8. The method of claim 1, wherein the providing further includes providing a planarizing layer about the gate prior to the removing for the at least a portion of the gate.

9. The method of claim 1, further comprising etching back the replacement gate.

10. The method of claim 1, wherein the providing further includes providing a metal layer over the transistor prior to the intrinsically stressed material, and the gate removing includes removing a portion of the metal layer over the gate;
wherein the replacement gate includes a metal;
further comprising:
annealing prior to the intrinsically stressed material removing to form a silicide from the metal in the replacement gate and to form a silicide in a source/drain region of the transistor from the metal layer and to memorize the stress from the intrinsically stressed material in the silicide;
removing at least a portion of the replacement gate prior to the intrinsically stressed material removing; and
removing the metal layer.

11. The method of claim 10, wherein the metal layer includes a first metal layer including one of nickel (Ni), cobalt (Co), titanium (Ti) and osmium (Os), and a second titanium nitride (TiN) layer.

12. A method of stressing a channel of a transistor, the method comprising:
first providing a metal layer over the transistor including a gate and a source/drain region thereof;
second providing an intrinsically stressed material over the transistor including the gate and the source/drain region thereof;
removing a portion of the intrinsically stressed material over each gate;
removing a portion of the metal layer over the gate;
removing at least a portion of the gate;
replacing the gate with a metal;
annealing to form a stressed silicide gate and stressed silicide portions in the source/drain region; and
removing the intrinsically stressed material and the metal layer.

13. The method of claim 12, wherein the first providing includes providing an intrinsically tensilely stressed material over an n-channel transistor and an intrinsically compressively stressed material over a p-channel transistor.

14. The method of claim 12, wherein the metal layer includes a first metal layer including one of nickel (Ni), cobalt (Co), titanium (Ti) and osmium (Os), and a second titanium nitride (TiN) layer, and the stressed silicide gate includes a silicide of the first metal.

15. The method of claim 12, wherein the intrinsically stressed material removing includes performing a reactive ion etch (RIE) to the metal layer.

16. The method of claim 12, wherein the gate portion removing includes performing a reactive ion etch (RIE) selective to a polysilicon portion of the gate.
